(19) United States
(12) Patent Application Publication
(10) Pub. No.: US 2010/0033175 A1
(43) Pub. Date: Feb. 11, 2010

(54) MAGNETO-RESISTIVE SENSOR

(75) Inventors: Hans Boeve, Hechtel-Eksel (BE); Stephan Jansen, Oss (NL); Teunis Jan Ikkink, Geldrop (NL); Harris Duric, Helmond (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/532,206

(22) PCT Filed: Mar. 11, 2008
(86) PCT No.: PCT/IB08/50875

§ 371 Date: Sep. 21, 2009

(30) Foreign Application Priority Data
Mar. 30, 2007 (EP) 07105314.4

(51) Int. Cl. G01R 33/09

(52) U.S. Cl. 324/252

(57) ABSTRACT

A high-performance, integrated AMR sensor has compensation and flipping coils for signal conditioning of the sensor output. At least one of the coils is formed in the laminate that connects the AMR sensor with its IC within a single package. As a result, the dimensions of the die area of the AMR sensor and the package size can be kept small.

### FIELD OF THE INVENTION

The invention relates to a circuit with a magneto-resistive sensor.

### BACKGROUND OF THE INVENTION

Magneto-resistance (MR) is a material property of a whole family of ferromagnetic alloys that refers to a dependence of electrical resistance on the angle between the direction of the electrical current flowing through the material and the orientation of an external magnetic field relative to the direction of the current. The effect is attributed to a larger probability of s-d scattering of electrons in the direction of the magnetic field. The net effect is that the electrical resistance maximum value when the direction of current is parallel to the applied magnetic field. An example of such material is a ferromagnetic material called “permalloy” (19% Fe, 81% Ni).

MR materials can be used to create magnetic field sensors, also referred to as magneto-meters. Operation and examples of such sensors are described in Application Note AN 00022 “Electronic Compass Design using KMZ51 and KMZ52”, author Thomas Stork, of Philips Semiconductors, dated Mar. 30, 2000. The KMZ52 is a commercially available electronic device manufactured by Philips that comprises the components of a compass sensor system within one package: two weak-field sensors with 90° displacement, each having a set/reset (flip) coil and a compensation coil. Typical current levels are 10 mA for the compensation coil and 1 A for the flip coil. About 2 mA is sufficient to balance the earth magnetic field. Therefore, the resistance of the flip coil is preferably relatively low, e.g., in the order of a few Ohms. Such sensors are manufactured using e.g., a thin-film technology or an integrated circuit technology.

Magnetic field sensors can be used in e.g., solid state compassing, metal detection, position detection, etc.

First, consider a sensor made of a simple strip of MR material. During fabrication, a strong external magnetic field is applied parallel to the strip's main axis. As a result, a preferred magnetization direction is defined in the strip. In the absence of a magnetic field, the magnetization always points into that direction. The operation of the sensor relies on two effects. The first effect is that the resistance of the strip depends on the angle between a direction of the current flowing through the strip and the direction of the magnetization. The second effect is that the direction of the magnetization, and therefore of the angle, can be influenced by an external magnetic field parallel to the strip and perpendicular to the preferred direction.

The simple strip sensor has a low sensitivity for small magnitudes of the external magnetic field. In addition, the simple sensor cannot discriminate between external magnetic fields of the same magnitude but with opposite directions. Therefore, the sensor has preferably a so-called “barber-pole” configuration. This is achieved by depositing e.g., aluminum stripes (called “barber poles”) on top of the MR strip at an angle of 45° to a main axis of the strip. As aluminum has in general a much higher conductivity than MR material, the effect of the barber pole is to rotate the current direction by 45°, effectively changing the angle between the magnetization of the MR material and the electrical current from an angle of magnitude “a” to an angle of magnitude “α-45°”. For weak magnetic fields such as the earth's field, the sensitivity now is significantly higher. In addition, the characteristic is linearized and allows detecting the sign of the external magnetic field.

In practice, it is advantageous to configure the sensor as a Wheatstone bridge, consisting of four magneto-resistive strips. For e.g., compass sensors, the barber pole structures are used, where one diagonal pair is orientated at +45° to the strip's main axis, and the other pair is orientated at −45°. Thus, the resistance variation due to a magnetic field is converted linearly into a variation of the differential output voltage. Moreover, the inherent temperature coefficients of the four bridge resistances are mutually compensated.

MR sensors are bi-stable by nature. That is, the direction of their internal magnetization can be inverted or “flipped”. This can be achieved by a magnetic field of sufficient strength, if that field is applied parallel to the magnetization, but having opposite direction. Flipping causes an inversion of the sensor characteristic, such that the sensor output voltage changes polarity. MR sensors can be stabilized against unwanted flipping by applying an auxiliary magnetic field parallel to the flipping axis. This auxiliary field should be pulsed, as a permanent field would decrease the sensitivity of the magnetometer. When measuring weak fields, it is even desired to invert or “flip” the sensor characteristic repetitively between consecutive magnetometer readings. This allows compensating the sensor's offset drift in a way comparable to the chopping technique used in the amplification of small electrical signals. A “set/reset” coil also referred to as “flip” coil, near the sensor element is a means to apply the auxiliary field for the flipping. In e.g., high-precision compass systems, the sensor must also allow to compensate for sensitivity drift with temperature and to compensate for interference fields. Both can be done by means of an auxiliary field in the field-sensitive direction that is perpendicular to the MR strips. This can be generated by a “compensation” coil near the sensor element.

Published European patent application EP 0 544 479 discloses an MR sensor created using a semiconductors manufacturing technology. In order to implement the functionalities of the auxiliary coils discussed above, the known sensor uses current straps. In one embodiment these current straps are formed in one or more metal layers implanted in the die wherein the barber-pole structures are formed. In another embodiment, the die is mounted on a ceramic carrier that has wire pads for electrically connecting the die to pads on the carrier. A separate conductive strap is positioned over the die. Current flowing through the strap flowing from one end to the other end causes the magnetic field.

### OBJECT AND SUMMARY OF THE INVENTION

The inventors propose an alternative configuration for the MR sensor that has additional advantages over the configuration of the known device.

To this end, the inventors propose an electronic circuit comprising a magneto-resistive sensor. The sensor has a magneto-resistive layer formed in a first substrate, e.g., a semiconductor device. The first substrate is mounted on a different, second substrate, e.g., a laminated substrate. The sensor has a conductive element for creating a magnetic field at the magneto-resistive layer to control the sensor by means of a current through the element. The element has the functionality of, e.g., a compensation coil and/or a flip coil as discussed above. The element is formed in the second substrate.

The magneto-resistive layer forms the heart of a magneto-resistive sensor. Magneto-resistive sensors can be fabricated on a variety of substrates such as a semiconductor, e.g. Si or III-V materials, glass or flexible materials such as polyimide. A magneto-resistive sensor usually comprises the magneto-resistive layer and a number of metal layers for interconnect and means for generating additional magnetic fields. A magneto-resistive sensor can further be integrated with an integrated circuit (IC) using CMOS or bipolar semiconductor processes, e.g. for signal conditioning purpose. This is usually done by post-processing in the sense that the sensor layers are added at the end of the back-end metallization steps of such process.

Laminated substrates are widely used in System-in-Package technology (or multi-chip modules) for high-density integration and can be rigid or flexible, and from organic or inorganic base material. Laminated substrates include (multilayer) laminate, e.g., Cu-FR4 based, as well as inorganic Low or High Temperature Cofired Ceramic substrates (LTCC-HTCC). From a system point-of-view the laminated substrate has a same function as multi-layer printed circuit board (PCB) technology. In Chip-Scale Packaging (CSP) the laminate that represents a multilayer PCB can be used to form the element, by flip-chip of the semiconductor device onto the board. In the latter case, logistics may be different in the sense that a semiconductor device can be offered to a customer who integrates the device in a board in a later stage of a manufacturing process. In System-in-Package, laminated substrate and semiconductor device are usually co-developed and integrated as a single product.

An advantage of integrating the element in the second substrate, e.g., the laminate, is that the element, e.g., the compensation coil and/or flip coil, does not need to affect the effective size of the first substrate, e.g., the die size of the sensor. One of the known implementations of an MR sensor in EP 0 544 479 has the auxiliary coils implemented in the die itself, thus requiring the size of the sensor die to be large enough that the coils can be accommodated, which leads to extra costs. Another one of the known implementations in EP 0 544 479 uses a current strap. The geometric configurations with straps may not be reproducible as well as having the coil implemented in the laminated substrate according to the invention, as the flatness of the latter introduces more predictability of the magnetic field behavior and current levels required.

Accordingly, an embodiment of the invention relates to a high-performance, integrated AMR sensor that has compensation and flipping coils for signal conditioning of the sensor output. At least one of the coils is formed in the laminate that connects the AMR sensor with its IC within a single package. As a result, the dimensions of the die area of the AMR sensor and the package size can be kept small.

The sensor's conductive element is formed within the substrate for creating a magnetic field by means of a current through the element. The element comprises a number of parallel current lines carrying the same current so that a magnetic field can be generated in the same direction over spatially distributed magnetic elements that form the magneto-resistive sensor. An elegant topology to design a number of parallel current lines carrying a same current is a two-dimensional spiral with two contacts to a current driver circuit. The second substrate carrying the element is particularly useful as a standard component for mounting thereon the magneto-resistive sensor and control circuitry for control of the sensor in operational use.

### BRIEF DESCRIPTION OF THE DRAWINGS

The invention is explained in further detail, by way of example and with reference to the accompanying drawing, wherein:

FIGS. 1, 2 and 3 are diagrams illustrating spatial configurations of a circuit according to the invention;

FIG. 4 gives a mathematical relationship between the magnetic field strength and various parameters representative of geometrical aspects of a spatial configuration; and

FIGS. 5, 6 and 7 are diagrams illustrating further spatial configurations of a circuit according to the invention.

Throughout the Figures, similar or corresponding features are indicated by same reference numerals.

### DESCRIPTION OF EMBODIMENTS

The invention relates to a high-performance, integrated MR sensor that is realized by adding compensation and/or flipping coils that enable signal conditioning of the sensor output. Compensation and flipping coils are usually added in metal layers on top of the sensitive layers that form the MR sensor in an integrated circuit technology. In the invention, however, at least one of the coils is positioned in the laminate that connects the MR sensor, with its IC, within a single package. Accordingly, the die area of the MR sensor, and hence the package size, can be kept at minimum dimensions, resulting in low-cost and a competitive advantage.

A compensation coil enables to set a magnetometer in a nulling mode, wherein the external magnetic field is compensated internally by a current flowing through the compensation coil. In essence, the compensation coil is able to generate magnetic fields in the sensitive direction of the sensor. As a result, the compensation coil allows for a full electrical test suite of the magnetometer. If not present, a dedicated test setup, e.g., using a Helmholtz coil configuration, is required for testing in a magnetic field.

An important parameter in the design is the magnetic field generation efficiency, in terms of A/m generated by 1 mA of current in the compensation coil. Different lay-outs can be implemented to generate high-ohmic (100's of Ohm) or low-ohmic (few Ohm) compensation coil designs.

In a magnetic field sensor, this compensation coil can be used in various ways: for operation in the nulling mode; as (magnetic) background cancellation for optimal mapping of sensor readout on ADC; for measuring of sensor sensitivity, e.g., so as to counter temperature effects; for use in a functional test in the electronic mode for simpler component test on wafer and package-level; as a self-test mode, e.g., as a life-death sensor test (final test, at start-up, while servicing).

Usually, the compensation coil is integrated in the metal stack above the integrated sensor element. Starting from the sensor element, a first metal layer serves the barber pole structure. The compensation coil is usually provided in a second metal layer. Finally, a flip (or set/reset) coil can be added in a third metal layer. Disadvantages of this approach are manifold. A more expensive manufacturing process is needed if a compensation coil is added as it requires an extra metal layer, which leads to a higher cost per unit area of die size. A larger sensor die size will be required if a compensation coil is added, whereas efficiency of the compensation coil layout is limited due to the fact that all sensor elements have to be subjected to a same direction of the generated magnetic field.

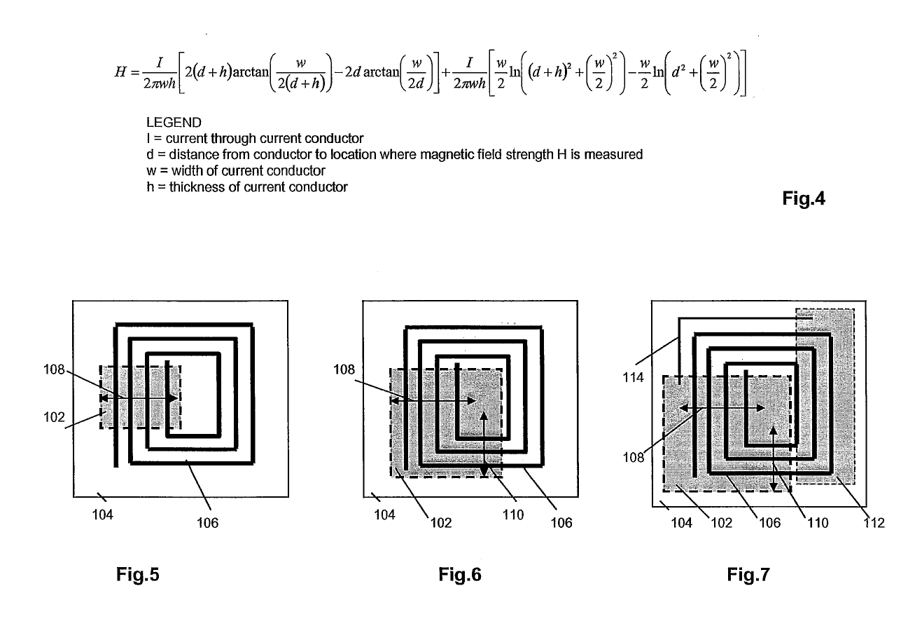

Given the geometry of a magnetic sensor die on a laminate, one can calculate the approximate magnetic field that is generated within the sensor. In a good approximation, the magnetic field strength is as given in formula (100) of FIG. 4. See the legend for an explanation of the symbols. Note that the maximum magnetic field occurs at the middle of a current line. A more complex approach gives the fall-off as function of deviation from the middle. As long as the distance is smaller than the width of the current conductor, the fall-off is rather small. However, the larger the distance to the current line, the faster will be the fall-off.

A magnetometer die can be thinned to a thickness of approximately 200 micron. Hence the minimum distance between the current line in the laminate and the magnetometer corresponds to the die thickness, plus some additional thickness for a glue. The minimum current line width on the laminate is in the order of tens of micron. Therefore, from the point of view of the magnetic field generation, a larger current line thickness is preferred. This, however, leads to a lower ohmic resistance and, hence, to a higher power consumption.

For example, a current of 10 mA and a current line width of 25 to 250 micron give a maximum magnetic field in the sensor of between 8 and 7 A/m, respectively, for a distance of about 200 micron. As discussed before, the fall-off will be less for the wider current line. To partially leverage for its low-resistance, a wider current line can be subdivided into a parallel connection of smaller current lines that are placed next to one another, so as to form a homogeneous field at a certain distance. The parallel connection of smaller current lines is preferably aligned to the respective magneto-resistive elements in the sensor design.

For an electronic compass, wherein the earth-magnetic field (typically 50 A/m) is measured, auxiliary magnetic fields are to be generated with a magnitude in the order of one-fifth to one-third of the earth-magnetic field for control of the proper operation (e.g., the compensation coil functionality and/or the flip coil functionality). In other words, for the example above, a current of 20 mA would be sufficient. It is to be noted that this approach would be of less value for a magnetometer that serves an application relying on nulling, since current levels would become too high for practical purposes in hand-held devices.

Depending on the scope of the eventual implementation (see above for different ways to use the compensation coil), an alternative implementation may use a less uniform or even non-uniform excitation field. For, e.g., a self-test application, it is sufficient to have a simple life-death response of the sensor to an excitation. Therefore, also a compensation coil that is only covering part of the sensor can be used for the purpose of this self-test. The simpler the compensation coil, the easier will be the integration of this feature into an electronic compass. The penalty will be a limited test feature (production test). Accordingly, some kind of calibration may be required so as to be able to fine-tune the self-test. It is anticipated that for a life-death self-test, the predictability of the conversion factor between the compensation current and the magneto-resistive sensor response (via the magnetic field) is to be high, so that calibration per batch of sensors suffices, and a calibration per individual sensor is not required. Preferably, threshold settings during production test take into account the tolerances. In particular, mounting of the sensor die onto the laminate will be critical. During sensor and laminate design and layout, tolerances must be taken into account. The approach described here may impose tighter tolerances on the placement of the sensor on the laminate.

The current is to be generated by the integrated circuit that can be part of the integrated magnetometer. Using standard bonding, e.g., flip-chip or wire bonding, the integrated circuit has intra-component connections to the laminate, whereby a current can be generated in the current line that is integrated in the laminate. Given the fact that the current line can be designed into a spiral coil and/or meander, a multi-level laminate may be required for interconnect purposes. However, additional signal lines and other interconnect lines between integrated circuit and magnetometer can be in the same plane as the (bulk of the) compensation coil.

In an alternative embodiment the multi-level laminate corresponds to a multilayer PCB whereby CSP flip-chip technology is used. The relevant distance between current line and magneto-resistive layer is set by the ball size of the flip-chip technology. For CSP flip-chip technology the ball size is in the order of 100 micron.

Given the fact that a compensation coil preferably provides a magnetic field in a same direction within the complete sensor, in practice not all of the area covered by the compensation coil can be used. Suppose that the compensation coil is designed as a square, spiral coil. For a one-dimensional (1D) magnetometer, only one-quarter of the perimeter of this coil can serve as compensation coil for this sensor. For a two-dimensional (2D) magnetometer, this may be one-half of the perimeter. Of course, one could use multiple 1D magnetometers and mount them so as to be sensitive to different directions, thus using at least half of the coil's area.

A key advantage of integrating the compensation coil in the laminate is that the effective die size of the sensor need not increase to be able to accommodate this coil. The coil can easily extend outside the magnetometer die in the laminate, to be partially placed even under the integrated circuit. As a result, expensive magnetometer die area is being exchanged for inexpensive laminate area, the area occupied by the integrated circuit not being a limiting factor.

In principle, for a flip coil a similar argumentation can be followed as for a comp coil. It is to be noticed that the flip coil generates a magnetic field that is perpendicular to the measurement direction of the magnetometer. The flip coil requires a low-resistive coil design, due to the high current levels required. Usually, the coil is a meander over oppositely aligned sensor elements.

Using a multilayer laminate, it would be possible to integrate both comp and flip coil in a laminate. However, given the fact that the required magnetic field for flipping of an electronic compass sensor is similar to existing magnetometer, it may not be the preferred choice to integrate a flip coil in the laminate, as current levels might become impractically high.

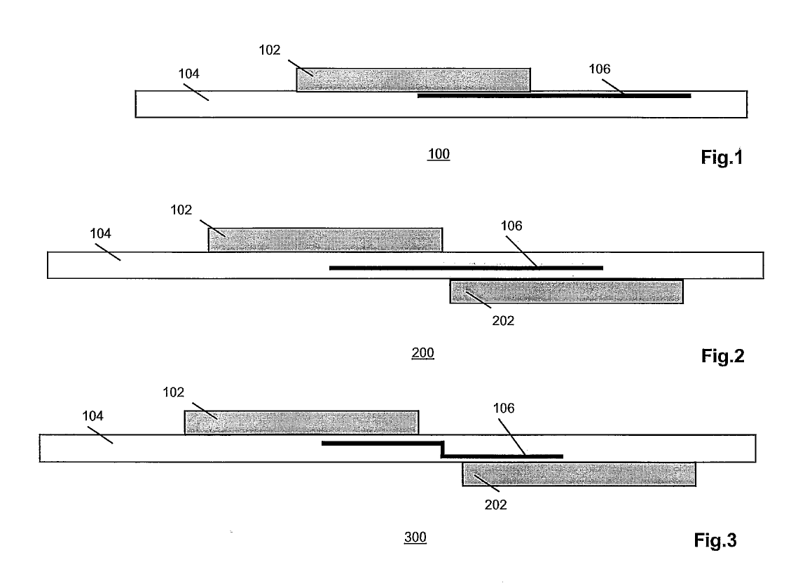

FIGS. 1, 2 and 3 are diagrams showing configurations of parts of devices 100, 200 and 300 in the invention. Devices 100, 200 and 300 are, for example, electronic compasses or magnetometers for other operational use.

Device 100 of FIG. 1 comprises a sensor die 102 mounted on a laminated substrate 104, e.g., an organic multi-layer laminate for a System-in-Package configuration. Substrate 104 provides mechanical support for die 102, as well as the galvanic connections to further circuitry (not shown) mounted on substrate 104 or accommodated elsewhere in device 100. Substrate 104 comprises a laminated configuration. In this example, the laminated configuration comprises multiple layers, e.g., one or more electrically conductive layers and one or more insulating layers stacked alternately. Each conductive layer can then be used for galvanic interconnections at a particular level in the layered configuration. In the invention, a specific layer 106 within the laminate is used to implement the auxiliary coil functionality.

Device 200 in FIG. 2 is somewhat similar to device 100, but differs in that the laminated substrate 104 is used to support a further sensor die 202 as well, so that specific layer 106 is stacked between them for combined control through the auxiliary coil functionality.

Device 300 of FIG. 3 is similar to device 200, but differs in that substrate 104 comprises multiple conductive layers 106 and 302. In this case, the auxiliary coil functionality is formed by connecting part of the conductive layer nearest to die 102, here layer 106, and part of another layer nearest to die 202, here layer 302, so as to minimize the distances between die 102 and die 202, on the one hand, and the auxiliary coil formed by layers 106 and 302, on the other hand.

Several other spatial configurations can be considered, e.g., a configuration (not shown) wherein multiple sensor dies are mounted on the same side of substrate 104 and wherein the auxiliary coil functionality for the multiple sensors is combined within a same conductive layer 106 extending at least partly underneath the multiple dies.

FIG. 5 is a diagram showing the spatial configuration of device 100 in top plan view. Sensor die 102 accommodates a 1D sensor in the form of one or more MR strips oriented in the same direction. Die 102 is mounted on substrate 104 relative to layer 106 implementing a compensation coil functionality, so that compensation coil 106 creates a magnetic field a more or less uniform magnetic field, i.e., pointing everywhere in the same direction within the MR strips of sensor die 102 oriented in the direction of arrow 108. As can be seen, roughly one quarter of the surface of coil 106 is used for a 1D sensor. Multiple dies, each with a 1D sensor could be mounted on substrate 104, oriented properly with respect to coil 106, and therefore with respect to the magnetic field generated by coil 106. As is clear from the drawing, coil 106 is functionally shaped as a spiral, which is easy from a layout point-of-view and an integration point-of-view. Given the three-dimensional option offered by a multilayer laminate one may opt for other design layouts for coil 106, exploiting the dimension perpendicular to the length and width of the laminate. In such design the criterion of a number of parallel current lines at the location of the magnetic elements of the magneto-resistive sensor must be fulfilled. One example is a compact three-dimensional spiral coil wherein the return paths are located in a different metal layer.

FIG. 6 is a diagram showing the spatial configuration of device 100 in top plan view, wherein sensor die 102 accommodates a 2D sensor. Again, die 102 is mounted relative to compensation coil 106 so that the latter generates a uniform magnetic field in each of the two 1D MR strips, positioned along arrows 108 and 110, respectively. Now, roughly half of the area occupied by coil 106 can be used.

FIG. 7 is a diagram of the configuration of FIG. 6, now showing in addition an integrated circuit 112 mounted on substrate 104 and connected to sensor die 102 via a conductive connection 114. Connection is implemented, e.g., using a conductive layer in multi-layer substrate 104 or another galvanic connection, e.g., a strap or a bonding wire. Circuit 112 is operative to, e.g., control operation of the sensor in die 102 and of coil 106, and/or to process the signals supplied by sensor die 102 for use by other circuitry (not shown) in device 100.

1. A magnetometer comprising:
a magneto-resistive layer formed in a semiconductor substrate;
a laminated substrate on which the semiconductor substrate is mounted; and
a compensation coil formed in a layer of the laminated substrate, wherein the compensation coil comprises a conductive element operable to create a magnetic field at the magneto-resistive layer to control the sensor by means of a current through the elements.

2. The magnetometer of claim 1, wherein:
the conductive element is functionally shaped as a spiral;
the magnetometer further comprises a second sensor with a second magneto-resistive layer formed in the semiconductor substrate; and
the semiconductor substrate is mounted on the laminated substrate relative to the element so as to cover a sector of an area of the spiral, the sector being substantially one-quarter of the area.

3. The magnetometer of claim 1, wherein the element extends beyond an area covered by the mounted substrate.

4. The magnetometer of claim 1, comprising a second sensor that has a second magneto-resistive layer formed in a third substrate, and wherein:
the semiconductor substrate and the third substrate are mounted at opposite sides of the laminated substrate and relative to the element so as to have the element being operative to create the magnetic field at the magneto-resistive layer and the second magneto-resistive layer to control the sensor and the second sensor.

5. The magnetometer of claim 1, further comprising a flipping coil comprising a second conductive element formed in a layer of the laminated substrate.
